(19) United States
(12) Patent Application Publication
(10) Pub. No.: US 2018/0083637 A1
(43) Pub. Date: Mar. 22, 2018

(54) FREQUENCY CALIBRATION METHOD FOR DIGITALLY CONTROLLED OSCILLATOR AND APPARATUS USING THE SAME

(71) Applicant: ANPEC ELECTRONICS CORPORATION, HSINCHU CITY (TW)

(72) Inventor: YUAN-HUNG WANG, MIAOLI COUNTY (TW)

(21) Appl. No.: 15/383,411

(22) Filed: Dec. 19, 2016

(30) Foreign Application Priority Data
Sep. 21, 2016 (TW) 105130447

(51) Int. Cl. H03L 7/00

(52) U.S. Cl. CPC H03L 7/00

(57) ABSTRACT

The present disclosure illustrates a frequency calibration method adapted to the digitally controlled oscillator (DCO) and apparatus using the same. The frequency calibration method can detect a degree of frequency offset between an actual frequency of a clock signal outputted by the digitally controlled oscillator and a desired frequency, and then performs the correlation calibration process accordingly to make sure that the frequency of the clock signal can approach to the desired frequency.

### BACKGROUND

### 1. Technical Field

The present disclosure relates to a frequency calibration method and apparatus using the same, in particular, to a frequency calibration method adapted to the digitally controlled oscillator (DCO) and apparatus using the same.

### 2. Description of Related Art

Generally, electronic products need to use a clock signal in operation process, but different electronic products employ clock signals having different oscillation frequencies. Thus, digitally controlled oscillators (DCO) which can output clock signals having different calibration frequencies by inputting control code have caught public attention and been widely applied to various electronic products. In addition, compared with voltage controlled oscillators (VCO), the oscillation frequency of the clock signal outputted by a DCO is not easily affected by the manufacturing process and other external environmental factors, and DCOs occupy a smaller area of a chip and are advantageous to reduce noise.

Despite the fact that DCOs gradually have become the core element in the phase-locked loops (PLL), there has not been any frequency calibration method adapted to DCOs and apparatus using the same provided to overcome the technical problems mentioned above.

### SUMMARY

The primary purpose of the present disclosure is to provide a frequency calibration method adapted to the digitally controlled oscillator (DCO) and apparatus using the same, wherein the DCO outputs a clock signal according to a control code it received, and the frequency calibration method comprises providing a counter to calculate a pulse number of the clock signal in a preset period according to a standard clock signal, and a control module to adjust a control code according to the pulse number to enable the DCO to output the clock signal according to the adjusted control code.

In a preferred embodiment, the counter determines the preset period according to a unit period of the standard clock signal, and calculates a period number of the clock signal at a rising edge in the unit period to be the pulse number.

In a preferred embodiment, the control module uses a desired number minus the pulse number to be an error value, and adds the error value to the control code to enable the DCO to increase, decrease or maintain the frequency of the clock signal according to the error value in the control code.

According to the another exemplary embodiment of the present disclosure, a frequency calibration apparatus adapted to a digitally controlled oscillator (DCO) is provided, wherein the DCO outputs a clock signal according to a control code it received, and the frequency calibration apparatus comprises a counter and a control module. The counter is connected to the DCO, and calculates a pulse number of the clock signal in a preset period according to a standard clock signal. The control module is connected between the counter and the DCO, and adjusts the control code according to the pulse number to enable the DCO to output clock signal according to the adjusted control code.

In a preferred embodiment, the counter determines the preset period according to a unit period of the standard clock signal, and calculates a period number of the clock signal at a rising edge in the unit period to be the pulse number.

In a preferred embodiment, the control module uses a desired number minus the pulse number to be an error value, and adds the error value to the control code to enable the DCO to increase, decrease or maintain the frequency of the clock signal according to the error value in the control code.

To sum up, without using complicated circuitry, the frequency calibration method adapted to the digitally controlled oscillator and apparatus using the same of the present disclosure are capable of effectively detecting a degree of frequency offset between a clock signal outputted by the digitally controlled oscillator in each unit period and a desired frequency through a counter. In addition, by adjusting the control code, the digitally controlled oscillator can output a clock signal having a desired frequency.

In order to further understand the techniques, means and effects of the present disclosure, the following detailed descriptions and appended drawings are hereby referred to, such that, and through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a flow chart of the frequency calibration method adapted to the digitally controlled oscillator of the present disclosure.

FIG. 2 is a function block diagram of one embodiment of the frequency calibration apparatus of the present disclosure.

FIG. 3 is a timing diagram illustrating the standard clock signal and the clock signal of the counter of the frequency calibration apparatus according to FIG. 2.

FIG. 4 is a schematic diagram of the control module of the frequency calibration apparatus according to FIG. 2.

FIG. 5 is a function block diagram of another embodiment of the frequency calibration apparatus of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

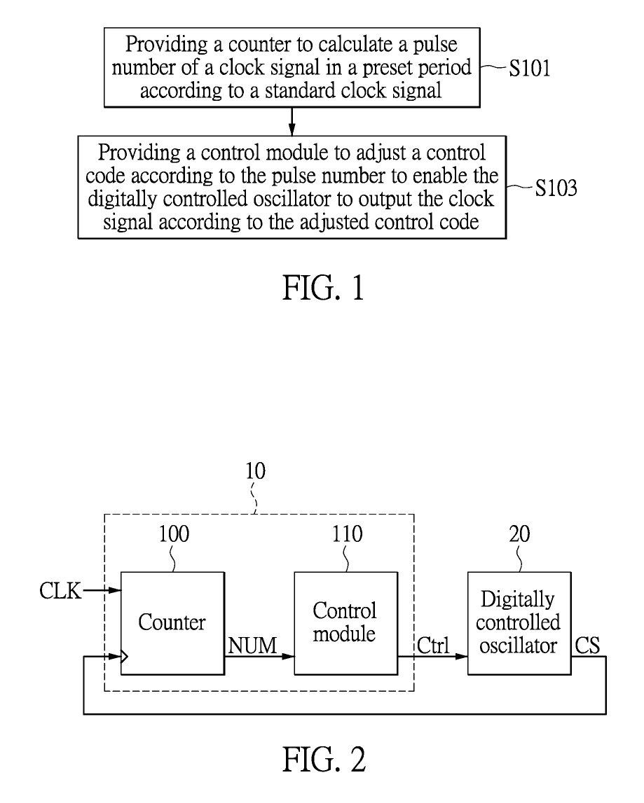

Please refer to FIG. 1 and FIG. 2 together which are respectively a flow chart of the frequency calibration method adapted to the digitally controlled oscillator of the present disclosure and a function block diagram of one embodiment of the frequency calibration apparatus of the present disclosure, wherein the frequency calibration method adapted to the digitally controlled oscillator shown in FIG. 1 is applicable to the frequency calibration apparatus shown in FIG. 2, but the present disclosure is not limited thereto. In addition, the frequency calibration apparatus of FIG. 2 is used to accomplish an aspect of the frequency calibration method adapted to the digitally controlled oscillator, and the present disclosure is not limited thereto, too.

Simply put, the frequency calibration method adapted to the digitally controlled oscillator and apparatus using the same provided by the present disclosure are applicable to any digitally controlled oscillator, and the present disclosure is not limited to a specific implementation thereof. As the action principle of the digitally controlled oscillator is well-known by those ordinarily skilled in the art, unnecessary details are not repeated hereinafter.

As shown in FIG. 2, a digitally controlled oscillator 20 outputs a clock signal having a desired frequency fout according to a control code Ctrl it received, but there may have been a degree of frequency offset producing between the actual frequency fout′ of the clock signal CS outputted by the digitally controlled oscillator 20 and the desired frequency fout because of the manufacturing process and other external environmental factors, that is, fout′ is not equal to fout. Thus, the frequency calibration method adapted to the digitally controlled oscillator and apparatus using the same of the present disclosure are provided to calibrate the actual frequency fout′ of the clock signal CS outputted by the digitally controlled oscillator 20 to enable the actual frequency fout′ of the clock signal CS to approach to the desired frequency fout.

A frequency calibration apparatus 10 may include a counter 100 and a control module 110 which may be made of hardware circuitry or hardware circuitry cooperating with flexible circuitry, but the present disclosure is not limited thereto. In addition, the counter 100 and the control module 110 may be integrated with each other or disposed separately, and the present disclosure is not limited thereto, too. That is to say, the present disclosure does not limit the specific implementation of the frequency calibration apparatus 10.

The counter 100 is connected to the digitally controlled oscillator 20, and calculates a pulse number NUM of the clock signal CS in a preset period (not shown) according to a standard clock signal CLK. The control module 110 is connected between the counter 100 and the digitally controlled oscillator 20, and adjusts the control code Ctrl according to the pulse number NUM to enable the digitally controlled oscillator 20 to output the clock signal CS according to the adjusted control code Ctrl.

The present embodiment does not limit the specific embodiment concerning the control code Ctrl to be first inputted to the digitally controlled oscillator 20. In other words, before operating the digitally controlled oscillator 20, the other control units (not shown) or the control module 110 can input an initialized control code Ctrl to the digitally controlled oscillator 20 to enable the digitally controlled oscillator 20 to output the clock signal CS according to the initialized control code Ctrl. After that, the counter 100 of the present embodiment starts to count the pulse number NUM.

Please refer to FIG. 1 again. When the frequency calibration method adapted to the digitally controlled oscillator 20 of the present disclosure is executed, it includes steps as follows. In S101, the frequency calibration apparatus 10 uses the counter 100 to count the pulse number NUM of the clock signal CS in a preset period (not shown) according to a standard clock signal CLK. In S103, the frequency calibration apparatus 10 uses the control module 110 to adjust the control code Ctrl according to the pulse number NUM to enable the digitally controlled oscillator 20 to output the clock signal CS according to the adjusted control code Ctrl.

According to the content mentioned above, those ordinarily skilled in the art would understand that the present disclosure uses the counter 100 to record the actual frequency fout′ of the clock signal CS outputted by the digitally controlled oscillator 20, and counts the pulse number NUM according to the actual frequency fout′. After that, the control module 100 is used to enable the digitally controlled oscillator 20 to increase, decrease or maintain the actual frequency fout′ of the clock signal CS outputting in the following unit period according to the pulse number NUM obtained from the counter 100. That is, the digitally controlled oscillator 20 is to output the clock signal CS according to the adjusted control code Ctrl.

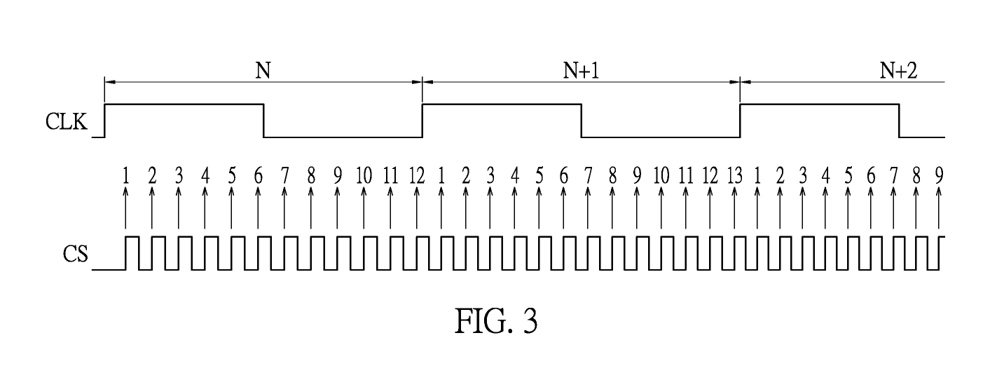

The implementation of the counter 100 of the present embodiment is described in detail as follows. Please refer to FIG. 3, which is a timing diagram illustrating the standard clock signal and the clock signal of the counter of the frequency calibration apparatus according to FIG. 2, wherein the elements respectively shown in FIG. 2 and FIG. 3 are denoted with the same reference indicators and unnecessary details are not repeated herein.

Specifically, the counter 100 determines a single period to be the preset period according to the standard clock signal CLK, and calculates the period number of the clock signal CS at a rising edge in the unit period to be the pulse number NUM. Thus, the frequency of the standard clock signal CLK used in the present embodiment has to be smaller than the frequency of the clock signal CS outputted by the digitally controlled oscillator 20 to enable the counter 100 to work normally.

That is to say, the present disclosure does not change the actual frequency fout′ of the clock signal CS in the current period (e.g. the first unit period N shown in FIG. 3) but calculates the period number of the clock signal CS at the rising edge in the period. As shown in FIG. 3, the pulse number NUM of the clock signal CS in the first unit period N is 12. As the counter 100 has a smaller circuit layout and is advantageous to reduce noise, the present disclosure is able to count frequency more effectively and maintain stability.

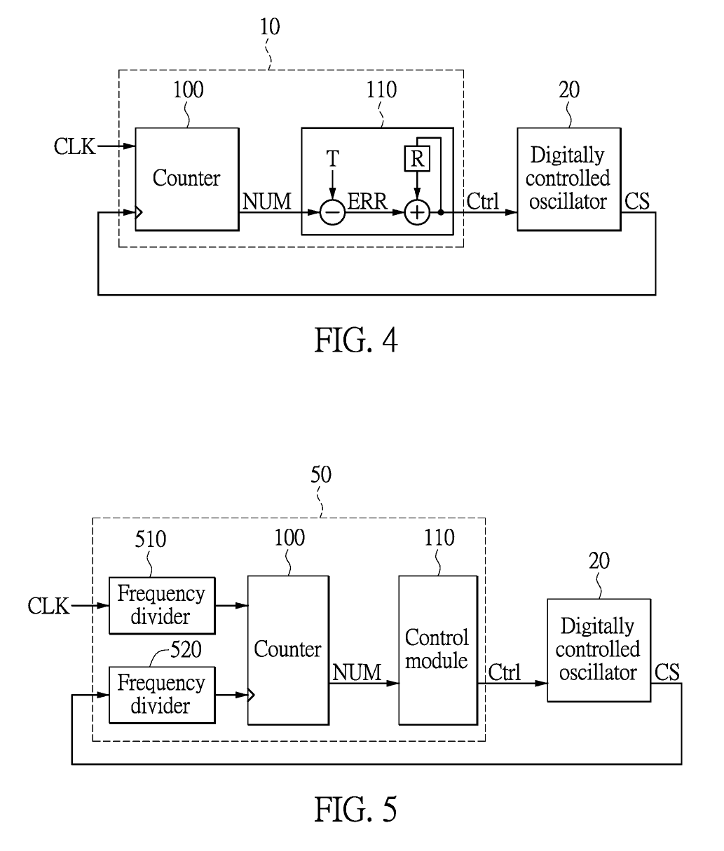

Please refer to FIG. 4 which is a schematic diagram of the control module of the frequency calibration apparatus according to FIG. 2, wherein the elements respectively shown in FIG. 4 and FIG. 2 are denoted with the same reference indicators and unnecessary details are not repeated herein.

Specifically, the counter 100 uses a desired number T minus the pulse number NUM to obtain an error value ERR, and then adds the error value ERR to the control code Ctrl to enable the digitally controlled oscillator 20 to increase, decrease or maintain the actual frequency fout′ of the clock signal CS according to the error value ERR in the control code Ctrl.

The present disclosure does not limit the specific implementation of the desired number T, and those ordinarily skilled in the art would define the desired number T according to the actual requirements. In addition, the present disclosure also does not limit the specific implementation of adding the error value ERR to the control code Ctrl, and those ordinarily skilled in the art would define it according to the actual requirements.

It should be understood that the desired number T can be defined to match the period number of the desired frequency fout of the clock signal CS at the rising edge in the unit period according to the standard clock signal CLK. Thus, the desired number T minus the pulse number NUM, namely, the error value ERR is used to indicate a degree of frequency offset between the actual frequency fout′ of the clock signal CS and the desired frequency fout.

For example, as shown in FIG. 3, if the desired number T is 14 and when the pulse number NUM of the clock signal CS in the first unit period N is 12, it points out that the error value ERR is +2. That is to say, the actual frequency fout′ of the clock signal CS outputted by the digitally controlled oscillator 20 in the first unit period N is smaller than the desired frequency fout (i.e. fout′<fout). Thus, the present disclosure controls the digitally controlled oscillator 20 to increase the actual frequency fout′ of the clock signal CS outputted by the digitally controlled oscillator 20 in the second unit period N+1. (i.e. the clock signal CS in the second unit period N+1 shown in FIG. 3), so that the actual frequency fout′ of the clock signal CS outputted by the digitally controlled oscillator 20 is calibrated to meet the desired frequency fout.

Please refer to FIG. 4. The control module 100 can add the error value ERR to the control code Ctrl outputted in the former period to be the adjusted control code Ctrl. Here, the control module 100 includes at least one register R which is used to store the content related to the control code Ctrl outputted in the former period. When receiving the control code Ctrl outputted in the former period, the digitally controlled oscillator 20 can determine the degree of frequency offset between the actual frequency fout′ of the clock signal CS outputted in the former period and the desired frequency fout according the error value ERR in the control code Ctrl. The implementation mentioned above is used as an example, and the present disclosure is not limited thereto.

According to the content mentioned previously those ordinarily skilled in the art would understand that when the error value ERR is zero, it means that the desired number T is equal to the pulse number NUM of the clock signal CS in the current period. That is to say, the actual frequency fout′ of the clock signal CS outputted by the digitally controlled oscillator 20 is equal to the desired frequency fout (i.e. fout′=fout). Thus, the present disclosure controls the digitally controlled oscillator 20 to maintain the actual frequency fout′ of the clock signal CS outputted by the digitally controlled oscillator 20. In other words, the digitally controlled oscillator 20 maintains the actual frequency fout′ of the clock signal CS outputted by the digitally controlled oscillator 20 according to the error value ERR.

On the one hand, when the error value ERR is a positive integer, it means that the desired number T is larger than the pulse number NUM of the clock signal CS in the current period. That is to say, the actual frequency fout′ of the clock signal CS outputted by the digitally controlled oscillator 20 is smaller than the desired frequency fout (i.e. fout′<fout). Thus, the present disclosure controls the digitally controlled oscillator 20 to increase the actual frequency fout′ of the clock signal CS outputted by the digitally controlled oscillator 20. In other words, the digitally controlled oscillator 20 increases the actual frequency fout′ of the clock signal outputted by the digitally controlled oscillator 20 according to the error value ERR.

On the other hand, when the error value ERR is a negative integer, it means that the desired number T is smaller than the pulse number NUM of the clock signal CS in the current period. That is to say, the actual frequency fout′ of the clock signal CS outputted by the digitally controlled oscillator 20 is higher than the desired frequency fout (i.e. fout′>fout). Thus, the present disclosure controls the digitally controlled oscillator 20 to decrease the actual frequency fout′ of the clock signal CS outputted by the digitally controlled oscillator 20. In other words, the digitally controlled oscillator 20 decreases the actual frequency fout′ of the clock signal CS outputted by the digitally controlled oscillator 20 according to the error value ERR.

Each implementation mentioned above is used as an example, and the present disclosure is not limited thereto. In addition, the present disclosure does not limit the specific implementation of the digitally controlled oscillator 20 increasing or decreasing the actual frequency fout′ of the clock signal CS and those ordinarily skilled in the art should be able to make it according to the actual requirements.

Please refer to FIG. 3 again. As the pulse number NUM (13) of the clock signal CS in the second unit period N+1 is still smaller than the desired number T (14), the present disclosure continuously controls the digitally controlled oscillator 20 to increase the actual frequency fout′ of the clock signal CS outputting in the following unit period till the pulse number NUM of the clock signal CS in the i^{th} unit period N+i (i is a positive integer equal to or larger than 2) is equal to the desired number T (14). By means of the frequency calibration method adapted to the digitally controlled oscillator and apparatus using the same provided by the present disclosure, the digitally controlled oscillator 20 is controlled to maintain the actual frequency fout′ of the clock signal CS it outputted.

Similarly, when the pulse number NUM of the clock signal CS in the j^{th} unit period N+j (j is a positive integer equal to or larger than 2, and j is larger than i) is not equal to the desired number T (14), the present disclosure continuously controls the digitally controlled oscillator 20 to selectively increase or decrease the actual frequency fout′ of the clock signal CS outputting in the following unit period, thereby enabling the actual frequency fout′ of the clock signal CS to be continuously calibrated to approach to the desired frequency fout effectively.

The present disclosure is capable of effectively detecting a degree of frequency offset (i.e. the error value) between the actual frequency of the clock signal outputted by the digitally controlled oscillator in each unit period and the desired frequency to calibrate the frequency accordingly, so as to ensure the clock signal outputted by the digitally controlled oscillator meets the desired frequency.

Generally, a counter is cooperated with a frequency divider to increase the solution of the counter so as to achieve better measurement precision. The present disclosure further provides an embodiment which can refer to FIG. 5. FIG. 5 is a function block diagram of another embodiment of the frequency calibration apparatus of the present disclosure, and the elements respectively shown in FIG. 5 and FIG. 2 are denoted with the same reference indicators and unnecessary details are not repeated herein.

Compared with the frequency calibration apparatus 10 shown in FIG. 2, the frequency calibration apparatus 50 shown in FIG. 5 further includes frequency dividers 510, 520, wherein the frequency divider 510 is used to divide the frequency of the clock signal CS, and the frequency divider 520 is used to divide the frequency of the standard clock signal CLK. Here, the action principle of the frequency dividers 510, 520 is well-known by those of ordinary skill in the art and unnecessary details are not repeated herein. According to the content mentioned previously it would be understood that the counter 100 is capable of effectively improving the detection of a degree of frequency offset of clock signal without affecting the frequency calibration method provided by the present disclosure. In addition, for the implementation of the frequency calibration apparatus 50 shown in FIG. 5 executing the frequency calibration method adapted to the digitally controlled oscillator refer to the aforementioned embodiments, and unnecessary details are not repeated.

In summary, without using complicated circuitry, the frequency calibration method adapted to the digitally controlled oscillator and apparatus using the same of the present disclosure are capable of effectively detecting a degree of frequency offset between a clock signal outputted by the digitally controlled oscillator in each unit period and a desired frequency through a counter. In addition, by adjusting the control code, the digitally controlled oscillator can output a clock signal having a desired frequency.

The above-mentioned descriptions represent merely the exemplary embodiment of the present disclosure, without any intention to limit the scope of the present disclosure thereto. Various equivalent changes, alterations or modifications based on the claims of the present disclosure are all consequently viewed as being embraced by the scope of the present disclosure.

What is claimed is:

1. A frequency calibration method adapted to a digitally controlled oscillator (DCO), wherein the DCO outputs a clock signal according to a control code it received and the frequency calibration method comprises:
providing a counter to calculate a pulse number of the clock signal in a preset period according to a standard clock signal, and
providing a control module to adjust the control code to enable the DCO to output the clock signal according to the adjusted control code.

2. The frequency calibration method for the DCO according to claim 1, wherein the counter determines the preset period according to a unit period of the standard clock signal, and calculates a period number of the clock signal at a rising edge in the unit period to be the pulse number.

3. The frequency calibration method for DCO according to claim 2, wherein the control module uses a desired number minus the pulse number to be an error value, and adds the error value to the control code to enable the DCO to increase, decrease or maintain the frequency of the clock signal according to the error value in the control code.

4. The frequency calibration method for the DCO according to claim 3, wherein when the error value is zero, the DCO maintains the frequency of the clock signal according to the error value.

5. The frequency calibration method for the DCO according to claim 3, wherein when the error value is a positive integer, the DCO increases the frequency of the clock signal according to the error value.

6. The frequency calibration method for the DCO according to claim 3, wherein when the error value is a negative integer, the DCO decreases the frequency of the clock signal according to the error value.

7. A frequency calibration apparatus adapted to a digitally controlled oscillator (DCO), wherein the DCO outputs a clock signal according to a control code it received, and the frequency calibration apparatus comprises:
a counter connected to the DCO, and calculating a pulse number of the clock signal in a preset period according to a standard clock signal, and
a control module connected between the counter and the DCO, and adjusting the control code according to the pulse number to enable the DCO to output clock signal according to the adjusted control code.

8. The frequency calibration apparatus according to claim 7, wherein the counter determines the preset period according to a unit period of the standard clock signal, and calculates a period number of the clock signal at a rising edge in the unit period to be the pulse number.

9. The frequency calibration apparatus according to claim 8, wherein the control module uses a desired number minus the pulse number to be an error value, and adds the error value to the control code to enable the DCO to increase, decrease or maintain the frequency of the clock signal according to the error value in the control code.

10. The frequency calibration apparatus according to claim 9, wherein when the error value is zero, the DCO maintains the frequency of the clock signal according to the error value.

11. The frequency calibration apparatus according to claim 9, wherein when the error value is a positive integer, the DCO increases the frequency of the clock signal according to the error value.

12. The frequency calibration apparatus according to claim 9, wherein when the error value is a negative integer, the DCO decreases the frequency of the clock signal according to the error value.
